(19) United States
(12) Patent Application Publication
(10) Pub. No.: US 2003/0001243 A1
(43) Pub. Date: Jan. 2, 2003

(54) Method of monitoring ultra-thin nitride quality by wet re-oxidation

(76) Inventors: Yung-Hsien Wu, Taipei (TW); Chung Pei Chao, Taipei (TW); Chia-Lin Ku, Chu Pai City (TW)

Correspondence Address: STEVENS, DAVIS, MILLER & MOSHER, LLP, Suite 850, 1615 L Street, N.W., Washington, DC, 20036, US

(21) Appl. No.: 09/883,265

(22) Filed: Jun. 19, 2001

(51) Int. Cl. H01L 23/58; H01L 21/302; H01L 21/461

(52) U.S. Cl. 257/649; 438/724

(57) ABSTRACT

A method for monitoring the uniformity or quality of ultra-thin silicon nitride film uses wet re-oxidation of thin nitride to monitor its thickness variation to evaluate its quality. For nitride films with similar thicknesses, thinner oxide implies superior quality of the original nitride film and vice versa. The method of the present invention extends the use of ellipsometer measurement tools to the sub 10 Å level.

### BACKGROUND OF THE INVENTION

1. Field of the Invention

The present invention relates to a method of monitoring the quality of ultra-thin films formed on a substrate, such as a silicon wafer. More particularly, the present invention relates to a method for monitoring the quality of ultra-thin nitride formed on a semiconductor device.

2. Discussion of Related Art

Thin films for use in ULSI fabrication must satisfy inter alia a large set of structural requirements. Film thickness must be strictly controlled to facilitate etching of submicron features. Very low densities of film imperfections, such as thickness variances, become critical for the small linewidths, high densities, and large areas necessary for ULSI.

The formation of such films is accomplished by a large variety of techniques including thermal oxidation and nitridation of single crystal (and poly) silicon and there have been extensive studies addressing fabrication of reliable thin gate dielectrics for ULSI technology. Silicon nitride is generally regarded as a promising candidate to substitute for silicon dioxide, due to its high dielectric constant and other electrical characteristics that could dramatically improve device performance. In addition to its potential use as a gate dielectric, ultra-thin (<10 Å) silicon nitride also plays an important role in BuriEd STrap (BEST) cell formation, which is an advanced technology used to fabricate DRAM chips using trench capacitors. In this technology, silicon nitride acts as a barrier for preventing direct contact between poly-Si inside the trench and single crystalline substrate Si at the corner of a trench structure. Such contact would result in undesirable dislocations and defects during any subsequent thermal cycle, and would result in degradation of device performance as well as reduce charge retention time to an unacceptable level. Even with such a critical need for accurate assessment of the uniformity of ultra-thin films, there is still no efficient way to monitor the quality of this thin nitride film. The trend in ultra-thin film measurement (metrology) is toward more integrated metrology, i.e., metrology is undergoing a transition from stand-alone status to full integration with other capital systems used in the semiconductor fabrication process.

Ultra-thin gate oxides are critical to chip performance and have driven the development of ellipsometer measuring techniques that can precisely measure gate films with thicknesses of 20-30 Å down into the teens. Absolute ellipsometer measurement techniques that now give milli-Angstrom-range repeatability, have been developed and are commonly used in fabrication processes. Thus, there is a considerable investment in this existing measurement technology and a resulting keen interest in keeping it in place and viable for current processes as they incorporate even thinner films.

As architectures shrink further, films will get even thinner. However, for ultra-thin films (<10 Å), the ellipsometer does not provide accurate measurements due to the existence of native oxide. Current ellipsometer technology cannot be used to distinguish native oxide from nitride for such ultra-thin films.

Uniform film thickness as a metric of quality will increase in importance as films become thinner. The development of alternatives to ellipsometry requires the exploration of various approaches to making semiconductor devices, such as measuring ultra-thin film performance or measuring etching rate during fabrication. These are two possible alternative methods to monitor device quality either electrically or physically. However, these possible methods are not currently feasible. The former technique is time and resource intensive. The latter technique is very difficult in practice because the ultra-thin nitride layer is too thin to measure. Auger electron analysis (AES) or secondary ion mass spectroscopy (SIMS) are perhaps alternative approaches for this purpose, but, unfortunately these types of analysis are also impractical because they too are time intensive. These approaches are compared in the following table.

| Possible | Device | Etching | AES or SIMS |
|---|---|---|---|
| Approach | Fabrication | Rate | Analysis |
| Practical | Determine | FILM IS | Directly assess |
| Consideration | quality by | TOO THIN | film quality- |
| | measuring | to measure | TIME |
| | electrical | etching | CONSUMING |
| | characteristics- | rate | |
| | TIME CONSUMING | | |
| Feasibility | NO | NO | NO |

### SUMMARY OF THE INVENTION

Therefore, a simple technique is needed to monitor ultra-thin nitride quality in a more efficient way. The present invention provides such a monitoring technique that relies on the fact that an ultra-thin nitride film of uniform thickness possesses more ideal stoichiometry than films with thickness variations.

The present invention performs a wet re-oxidation of ultra-thin nitride film on a monitor wafer and then employs an optical probe to determine the quality of the original film by measuring the thickness of the re-oxidized film. Films with more ideal stoichiometry retard the re-oxidation growth rate.

Thus, by using the present invention, ellipsometer monitoring methods can be retained thereby extending the useful life of this commonly used monitoring technique. Any thickness variation in the original ultra-thin nitride film results in distinct differences in thickness after wet oxidation, i.e., the wet re-oxidation magnifies any original variation in thickness. Experimental results have confirmed that the thicker the original nitride, the thinner the oxide after re-oxidation. This fact is used, in the present invention, to evaluate the quality of ultra-thin silicon nitride films.

Another advantage of the present invention is that it can be integrated with ellipsometer monitoring of samples having thin nitride or only native oxide. Through the use of the present invention, tiny thickness differences on such wafers can be magnified by re-oxidation and easily observed.

Although wet oxidation is also time intensive, it still appears to be the fastest and most reliable way currently available to assess the quality of thin nitride. More importantly, this technique is simple and fully compatible with existing device fabrication processes.

The present invention provides a method that is compatible with existing semiconductor fabrication processes by using wet re-oxidation of an ultra-thin nitride layer deposited on a semiconductor device to assess the quality of the uniformity of the ultra-thin layer.

### BRIEF DESCRIPTION OF THE DRAWINGS

FIG. 1A illustrates experimental results of the effect of a pre-clean treatment with dilute hydrofluoric (DHF) acid, on thickness after re-oxidation.

FIG. 1B illustrates experimental results of thickness after re-oxidation alone, i.e., without pre-clean treatment.

FIG. 2 illustrates the correlation between buried strap (BS) nitride thickness before and after re-oxidation.

### DETAILED DESCRIPTION OF PREFERRED EMBODIMENT

In a preferred embodiment of the present invention, wafers of ultra-thin silicon nitride are re-oxidized in a wet ambient at 850° C. Through measurement of the variation in the thickness of the ultra-thin silicon nitride film after re-oxidation, the quality of the original silicon nitride film can be monitored. Ultra-thin silicon nitride film of uniform thickness is considered to be of high quality. Silicon nitride film with uniform thickness possesses more ideal stoichiometry that retards the growth rate of re-oxidation. Based on this mechanism, evident thickness differences after re-oxidation can be observed for original ultra-thin nitride films with different qualities.

Ellipsometer measurement techniques are error prone at ultra-thin film thickness levels because the ellipsometer is unable to distinguish native oxide from nitride. Therefore, experiments were conducted to establish the effects of pre-cleaning monitor wafers to remove native oxide.

In these experiments, different qualities (thicknesses) of ultra-thin silicon nitride films were prepared by nitridation on bare wafers with and without pre-clean by diluted hydrofluoric (DHF) dip in which the ratio is H₂O:HF=200:1. Wafers with these two treatments were placed on board in adjacent slots to avoid any position-dependent effect on nitride growth. The nitride growth process took place in NH₃ ambient at 700° C. for 30 minutes.

Ellipsometer measurements were taken to determine whether or not the pre-clean treatment had any effect on thickness after re-oxidation. Even with wafers having similar starting nitride thicknesses, there is an obvious thickness discrepancy after re-oxidation in wet ambient that grows 300 Å oxide on bare Si. Nitride with the pre-clean treatment demonstrates much thinner oxide growth, average of 112 Å, than the oxide without this treatment, average of 220 Å.

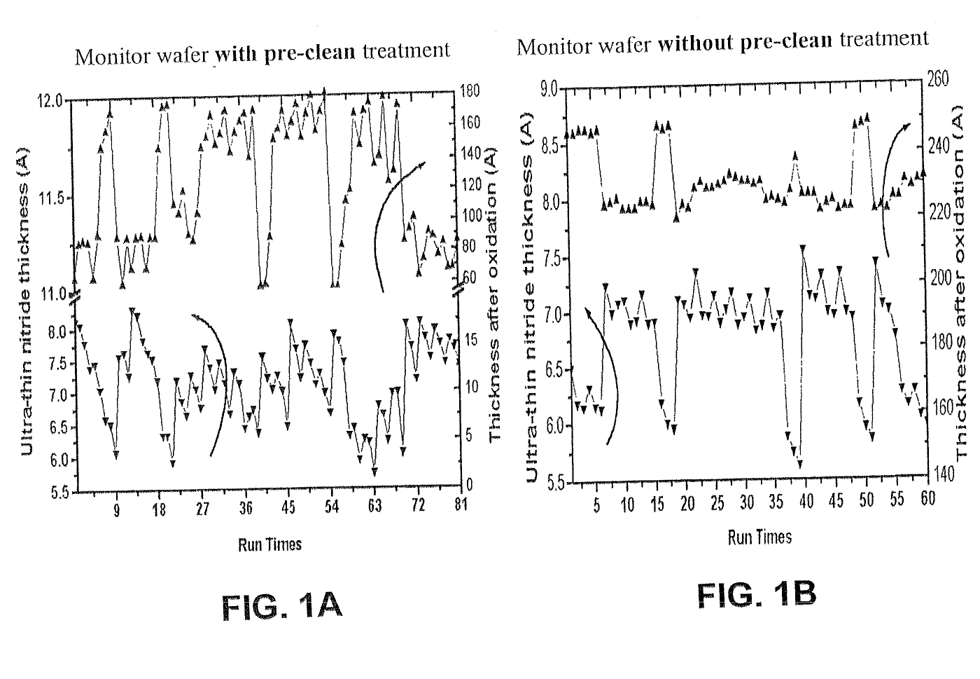

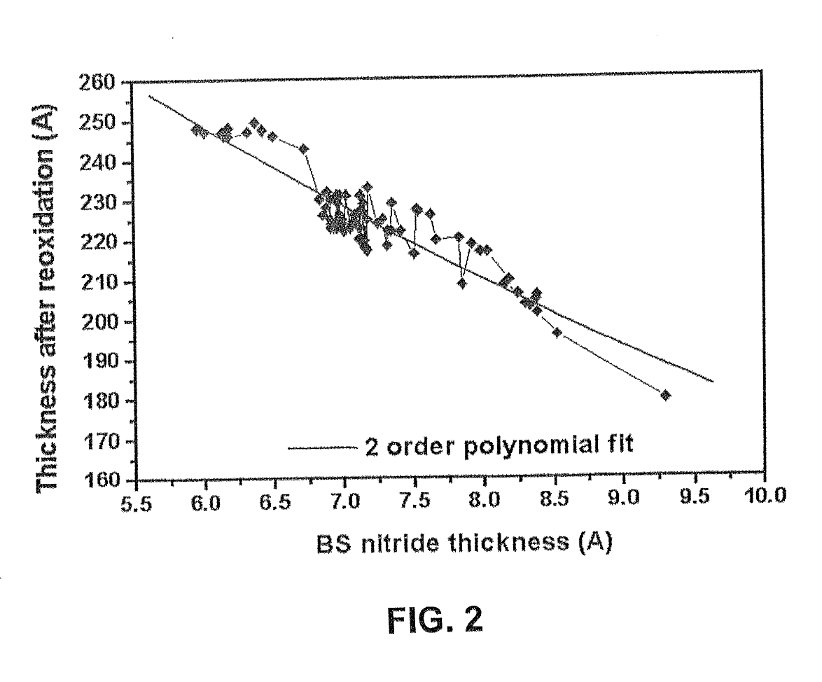

Referring now to FIGS. 1A-B, a further effect of pre-cleaning can be observed. In FIG. 1A, which represents wafer subjected to the DHF pre-clean treatment, the measurements of thickness both before and after re-oxidation demonstrate considerable variability when compared to the same measurements made of a wafer without such treatment. This phenomenon can be ascribed to the fact that wafers with pre-clean treatment are more prone to extrinsic oxygen encroachment that renders the quality of the nitride unstable and severely affects the thickness after subsequent re-oxidation. In spite of much less native oxide on pre-cleaned wafers, the pre-cleaned wafers are very sensitive to any extrinsic oxygen encroachment that severely affects the wafers' surface condition and subsequent nitride quality. By contrast, monitor wafers without pre-clean treatment exhibit a more stable thickness after re-oxidation. The native oxide appears to keep the surface condition of the nitride more stable.

Although pre-clean treatment is the current POR step for production wafers, the above-discussed results eliminated pre-clean as a component of the present invention. That is, monitor wafers without pre-clean treatment is the preferred embodiment of the present invention for monitoring ultra-thin film quality. Nitride with more stable quality can be obtained in monitor wafers without pre-clean treatment. According to FIG. 1B, the thickness of SiO₂ is between 210-250 Å with the nitride remaining within a standard specification of 5-9 Å.

The experiments also consistently resulted in thinner oxide for monitor wafers having thicker starting nitride. This phenomenon is reasonable because it is more difficult for oxidizing species to penetrate thicker nitride to the underlying Si to grow oxide.

Another advantage of this technique derives from the fact that it enables current ellipsometer technology to be employed to distinguish between native oxide and thin nitride. Through the use of the present invention, tiny differences in nitride thickness on a wafer are magnified and observed using an optical probe after oxidation.

The present invention provides a method employing wet re-oxidation for indirectly monitoring ultra-thin nitride film quality that incorporates an optical probe. It is both simple and compatible with current fabrication processes and even extends their useful lifetimes.

While there has been described a preferred embodiment for demonstrating the quality of ultra-thin silicon nitride films, it will be apparent to those skilled in the art that modifications and variations are possible without deviating from the broad scope of the invention which shall be limited solely by the scope of the claims appended hereto.

What is claimed is:

1. A method of monitoring quality of ultra-thin nitride films, said method comprising:
(a) providing a monitor wafer comprising a substrate with an ultra-thin film of silicon nitride deposited thereon;
(b) re-oxidizing said ultra-thin film in a wet ambient;
(c) measuring, at a plurality of different points, thickness of oxide that results from step (b);
(d) determining a degree of thickness variation of the ultra-thin film of silicon nitride provided by step (a) based on measurements of step (c); and
(e) ascertaining quality of the ultra-thin film of silicon nitride provided by step (a) in accordance with said degree of thickness variation determined in step (d).

2. The method according to claim 1, wherein step (b) is performed at a temperature of 850° C.

3. The method according to claim 1, wherein step (c) is performed with an optical probe.

4. The method according to claim 2, wherein step (c) is performed with an optical probe.

5. The method according to claim 1, wherein said ultra-thin film has a thickness of <10 Å.

6. A process of fabricating a semiconductor device including a quality monitoring method according to claim 1.

7. A semiconductor device fabricated with a process including a quality monitoring method according to claim 1.
